(19) United States
(12) Patent Application Publication
(10) Pub. No.: US 2015/0249004 A1
(43) Pub. Date: Sep. 3, 2015

(54) METHOD OF FABRICATING NITRIDE FILM AND METHOD OF CONTROLLING COMPRESSIVE STRESS OF THE SAME

(71) Applicant: WONIK IPS CO., LTD., Gyeonggi-do (KR)

(72) Inventors: Kyungeun LEE, Gyeonggi-do (KR); Doohyun LA, Gyeonggi-do (KR); Junseok CHANG, Seoul (KR); Byungchul CHO, Gyeonggi-do (KR); Dongho RYU, Gyeonggi-do (KR); Juhwan PARK, Gyeonggi-do (KR); Youngjun KIM, Gyeonggi-do (KR)

(21) Appl. No.: 14/630,864

(22) Filed: Feb. 25, 2015

(30) Foreign Application Priority Data
Feb. 28, 2014 (KR) 10-2014-0024618
Jan. 8, 2015 (KR) 10-2015-0002730
Jan. 8, 2015 (KR) 10-2015-0002731

(51) Int. Cl. H01L 21/02; C23C 16/44; C23C 16/34; C23C 16/455

(52) U.S. Cl. CPC H01L 21/0228; H01L 21/02274; H01L 21/0217; C23C 16/45536; C23C 16/4408; C23C 16/34

(57) ABSTRACT

The present invention relates to a method of fabricating a nitride film, which may easily control compressive stress while stably maintaining the film quality using the atomic layer deposition, and the nitride film having compressive stress is formed on a substrate by performing a unit cycle at least one time, the unit cycle including: a first step of providing a source gas on the substrate to absorb at least of the source gas on the substrate; a second step of providing a first purge gas on the substrate; a third step of forming a unit deposition film on the substrate by providing the substrate with a stress controlling gas including a nitrogen gas (N₂) and a reaction gas containing nitrogen components (N) other than the nitrogen gas (N₂) in a plasma state; and a fourth step of providing a second purge gas on the substrate.

### CROSS-REFERENCE TO RELATED APPLICATIONS

This application claims priority to and the benefit of Korean Patent Application No. 10-2014-0024618 filed in the Korean Intellectual Property Office on Feb. 28, 2014, Korean Patent Application No. 10-2015-0002730 filed in the Korean Intellectual Property Office on Jan. 8, 2015 and Korean Patent Application No. 10-2015-0002731 filed in the Korean Intellectual Property Office on Jan. 8, 2015, the entire contents of which are incorporated herein by reference.

### TECHNICAL FIELD

The present invention relates to a method of fabricating a nitride film and a method of controlling compressive stress of the same, and more particularly, to a method of fabricating a nitride film using the atomic layer deposition and a method of controlling compressive stress of the same.

### BACKGROUND ART

In the methods of improving the performance of an electronic device, there is a method of changing electrical characteristics of an upper or lower material, which is deformed by a nitride film having stress. For example, in the fabrication of a CMOS device, a nitride film having compressive stress may be formed on the PMOS regions such that a local mesh deformation is generated in a channel region of a transistor. In this case, it is necessary to control the level of stress produced in a deposited nitride within a predetermined range. However, a known method of fabricating a nitride has a problem in that it is not easy to appropriately control the stress level of a nitride simultaneously with stably maintaining the film quality of the nitride.

### SUMMARY OF THE INVENTION

The present invention has been made in an effort to provide a method of fabricating a nitride film having predetermined compressive stress while maintaining a good film quality. However, this problem is exemplary, but the scope of the present invention is not limited thereby.

An exemplary embodiment of the present invention provides a method of fabricating a nitride film. In the method of fabricating a nitride film, a nitride film having compressive stress is formed on a substrate by performing a unit cycle at least one time, the unit cycle including: a first step of providing a source gas on the substrate to adsorb at least a part of the source gas on the substrate, a second step of providing a first purge gas on the substrate, a third step of forming a unit deposition film on the substrate by simultaneously providing the substrate with a stress controlling gas including a nitrogen gas (N₂) and a reaction gas containing nitrogen components (N) other than the nitrogen gas (N₂) in a plasma state, and a fourth step of providing a second purge gas on the substrate.

The method of fabricating a nitride film may be performed such that as compressive stress required for the nitride film is increased, the amount of nitrogen gas (N₂) provided on the substrate in the third step is increased.

In the method of fabricating a nitride film, the stress controlling gas may include a mixture gas of a nitrogen gas (N₂) and an inert gas. Furthermore, the method may be performed such that as the compressive stress required for the nitride film is increased in the third step, the relative ratio of the nitrogen gas (N₂) to the inert gas provided on the substrate is increased.

In the method of fabricating a nitride film, the inert gas may include at least one of helium (He), neon (Ne), argon (Ar), krypton (Kr), xenon (Xe), and radon (Rn).

In the method of fabricating a nitride film, it is possible to control the power or frequency of a power supply applied for forming the plasma in order to additionally control the compressive stress of the nitride film in the third step.

In the method of fabricating a nitride film, the plasma may be formed by a direct plasma system or a remote plasma system.

In the method of fabricating a nitride film, the plasma may be formed in a shower head disposed on the substrate to be provided on the substrate.

In the method of fabricating a nitride film, the first purge gas or the second purge gas may be constantly provided in the first to fourth steps.

In the method of fabricating a nitride film, at least one of the first purge gas and the second purge gas may be a nitrogen gas or an inert gas. Alternatively, at least one of the first purge gas and the second purge gas may be a mixture gas composed of a nitrogen gas and an inert gas. Furthermore, the stress controlling gas including a nitrogen gas (N₂) may be a gas composed of a material which is the same as at least one of the first purge gas and the second purge gas.

In the method of fabricating a nitride film, the unit cycle may further include: a fifth step of providing a second stress controlling gas in a plasma state on the unit deposition film; and a sixth step of providing a third purge gas on the substrate.

In the method of fabricating a nitride film, the second stress controlling gas may include a nitrogen gas (N₂), or include a mixture gas of an inert gas and a nitrogen gas (N₂).

In the method of fabricating a nitride film, the first purge gas, the second purge gas, or the third purge gas may be constantly provided in the first to sixth steps.

In the method of fabricating a nitride film, at least one of the first purge gas, the second purge gas, and the third purge gas may be a nitrogen gas or an inert gas.

In the method of fabricating a nitride film, at least one of the first purge gas, the second purge gas, and the third purge gas may be a mixture gas composed of a nitrogen gas and an inert gas.

In the method of fabricating a nitride film, the stress controlling gas may be a gas composed of a material which is the same as at least one of the first purge gas, the second purge gas, and the third purge gas.

In the method of fabricating a nitrogen film, the reaction gas containing nitrogen components (N) may include an ammonia (NH₃) gas.

Another exemplary embodiment of the present invention provides a method of controlling compressive stress of a nitride film. In the fabrication of a nitride film by the atomic layer deposition in which a unit cycle is performed repeatedly at least one time, the unit cycle includes simultaneously providing a substrate with a stress controlling gas including a nitrogen gas (N₂) and a reaction gas containing nitrogen components (N) other than the nitrogen gas (N₂) in a plasma state, and is performed such that as compressive stress required for the nitride film is increased, the amount of nitrogen gas provided on the substrate is controlled to be increased.

Still another exemplary embodiment of the present invention provides a method of fabricating a nitride film. In the method of fabricating a nitride film, a nitride film having compressive stress is formed on a substrate by performing a unit cycle at least one time, the unit cycle including: a first step of providing a source gas on the substrate to adsorb at least a part of the source gas on the substrate; a second step of providing a first purge gas on the substrate; a third step of forming a unit deposition film on the substrate by simultaneously providing the substrate with a stress controlling gas including a nitrogen gas (N₂) and a reaction gas containing nitrogen components (N) other than the nitrogen gas (N₂) in a plasma state; a fourth step of providing a second purge gas on the substrate; and a step of stopping providing the source gas and maintaining the pressure in the chamber lower than the pressure in the chamber in the first step after the first step and before the second step.

In the method of fabricating a nitride film, the maintaining of the pressure in the chamber lower than the pressure in the chamber in the first step may be implemented by performing pumping in the chamber while stopping providing the source gas. Furthermore, the pumping may be performed all the time throughout the unit cycle.

In the method of fabricating a nitride film, the unit cycle may include a step of stopping providing the stress controlling gas and the reaction gas and maintaining the pressure in the chamber lower than the pressure in the chamber in the third step, after the third step and before the fourth step.

In the method of fabricating a nitride film, the maintaining of the pressure in the chamber lower than the pressure in the chamber in the third step may be implemented by performing pumping in the chamber while stopping providing the stress controlling gas and the reaction gas. Furthermore, the pumping may be performed all the time throughout the unit cycle.

The method of fabricating a nitride film may be performed such that as compressive stress required for the nitride film is increased, the amount of nitrogen gas (N₂) provided on the substrate in the third step is increased.

In the method of fabricating a nitride film, the stress controlling gas may include a mixture gas of an inert gas and a nitrogen gas. The inert gas may include at least one of helium (He), neon (Ne), argon (Ar), krypton (Kr), xenon (Xe), and radon (Rn). Furthermore, the method may be performed such that as the compressive stress required for the nitride film is increased in the third step, the relative ratio of the nitrogen gas (N₂) to the inert gas provided on the substrate is increased.

In the method of fabricating a nitride film, it is possible to control the power or frequency of a power supply applied for forming the plasma in order to additionally control the compressive stress of the nitride film in the third step.

In the method of fabricating a nitride film, the plasma may be formed by a direct plasma system or a remote plasma system.

In the method of fabricating a nitride film, the plasma may be formed in a shower head disposed on the substrate to be provided on the substrate.

In the method of fabricating a nitride film, the first purge gas or the second purge gas may be constantly provided in the first to fourth steps.

In the method of fabricating a nitride film, at least one of the first purge gas and the second purge gas may be a nitrogen gas or an inert gas. Alternatively, at least one of the first purge gas and the second purge gas may be a mixture gas composed of a nitrogen gas and an inert gas. Furthermore, the stress controlling gas including a nitrogen gas (N₂) may be a gas composed of a material which is the same as at least one of the first purge gas and the second purge gas. The inert gas may include at least one of helium (He), neon (Ne), argon (Ar), krypton (Kr), xenon (Xe), and radon (Rn).

In the method of fabricating a nitride film, the unit cycle may further include: a fifth step of providing a second stress controlling gas in a plasma state on the unit deposition film; and a sixth step of providing a third purge gas on the substrate.

In the method of fabricating a nitride film, the second stress controlling gas may include a nitrogen gas (N₂), or include a mixture gas of an inert gas and a nitrogen gas (N₂). The inert gas may include at least one of helium (He), neon (Ne), argon (Ar), krypton (Kr), xenon (Xe), and radon (Rn).

In the method of fabricating a nitride film, the first purge gas, the second purge gas, or the third purge gas may be constantly provided in the first to sixth steps.

In the method of fabricating a nitride film, at least one of the first purge gas, the second purge gas, and the third purge gas may be a nitrogen gas or an inert gas. The inert gas may include at least one of helium (He), neon (Ne), argon (Ar), krypton (Kr), xenon (Xe), and radon (Rn).

In the method of fabricating a nitride film, at least one of the first purge gas, the second purge gas, and the third purge gas may be a mixture gas composed of a nitrogen gas and an inert gas. The inert gas may include at least one of helium (He), neon (Ne), argon (Ar), krypton (Kr), xenon (Xe), and radon (Rn).

In the method of fabricating a nitride film, the stress controlling gas may be a gas composed of a material which is the same as at least one of the first purge gas, the second purge gas, and the third purge gas.

In the method of fabricating a nitrogen film, the reaction gas containing nitrogen components (N) may include an ammonia (NH₃) gas.

According to some exemplary embodiments of the present invention configured as described above, it is possible to provide a method of fabricating a nitride film, which may appropriately control the stress level of the nitride film while stably maintaining the film quality of the nitride. Of course, the scope of the present invention is not limited by this effect.

### BRIEF DESCRIPTION OF THE DRAWINGS

FIG. 1 is a flowchart illustrating a unit cycle of the atomic layer deposition in a method of fabricating a nitride film according to an exemplary embodiment of the present invention.

FIG. 2 is a diagram sequentially illustrating a series of processes, to which a substrate is subjected over time during a unit cycle in the method of fabricating a nitride film according to the exemplary embodiment of the present invention, from the left side to the right side.

FIG. 3 is a diagram sequentially illustrating a series of processes, to which a substrate is subjected over time during a unit cycle in a modified method of fabricating a nitride film according to an exemplary embodiment of the present invention, from the left side to the right side.

FIG. 4 is a flowchart illustrating a unit cycle in a modified method of fabricating a nitride film according to another exemplary embodiment of the present invention.

FIG. 5 is a diagram sequentially illustrating a series of processes, to which a substrate is subjected over time during a unit cycle in the modified method of fabricating a nitride film according to another exemplary embodiment of the present invention, from the left side to the right side.

FIG. 6 is a diagram sequentially illustrating a series of processes, to which a substrate is subjected over time during a unit cycle in the modified method of fabricating a nitride film according to another exemplary embodiment of the present invention, from the left side to the right side.

FIG. 7 is a flowchart illustrating a unit cycle of the atomic layer deposition in a method of fabricating a nitride film according to still another exemplary embodiment of the present invention.

FIG. 8 is a diagram sequentially illustrating a series of processes, to which a substrate is subjected over time during a unit cycle in the method of fabricating a nitride film according to still another exemplary embodiment of the present invention, from the left side to the right side.

FIG. 9 is a diagram sequentially illustrating a series of processes, to which a substrate is subjected over time during a unit cycle in a modified method of fabricating a nitride film according to yet another exemplary embodiment of the present invention, from the left side to the right side.

FIG. 10 is a flowchart illustrating a unit cycle of the atomic layer deposition in a method of fabricating a nitride film according to still yet exemplary embodiment of the present invention.

FIG. 11 is a graph illustrating characteristics of compressive stress and a wet etch rate ratio (WERR) according to the flow rate of a nitrogen gas in a nitride film implemented by a method of fabricating a nitride film according to some exemplary embodiments of the present invention.

FIG. 12 is a graph illustrating characteristics of compressive stress and a wet etch rate ratio (WERR) according to the power of a power supply applied for forming a plasma in a nitride film implemented by a method of fabricating a nitride film according to the Comparative Examples of the present invention.

### DETAILED DESCRIPTION

Hereinafter, various exemplary embodiments of the present invention will be exemplarily described with reference to the accompanying drawings.

Throughout the present specification, it may be interpreted that when an element such as a film, a region, or a substrate is referred to as being positioned “on” another element, the one element may be contacted directly “on” the another element, or intervening elements may also be present therebetween. In contrast, it is interpreted that when an element is referred to as being positioned “directly on” another element, there are no intervening elements present therebetween.

Hereinafter, exemplary embodiments of the present invention will be described with reference to the drawings schematically illustrating ideal exemplary embodiments of the present invention. In the drawings, the illustrated shape may be expected to be modified according to, for example, a manufacturing technology and/or tolerance. Thus, exemplary embodiments of the present inventive spirit should not be construed to be limited to a particular shape of a region illustrated in the present specification, and should include, for example, a change in the shape generated during manufacturing. Further, in the drawings, the thickness of each layer or dimensions may be exaggerated for convenience of description or clarity. Like reference numerals indicate like elements.

The inert gas mentioned in the present invention may mean a rare gas. The rare gas specifically refers to at least one gas selected from helium (He), neon (Ne), argon (Ar), krypton (Kr), xenon (Xe), and radon (Rn). Accordingly, the inert gas mentioned in the present invention may include at least one of helium (He), neon (Ne), argon (Ar), krypton (Kr), xenon (Xe), and radon (Rn). Meanwhile, the inert gas mentioned in the present invention does not include nitrogen or carbon dioxide.

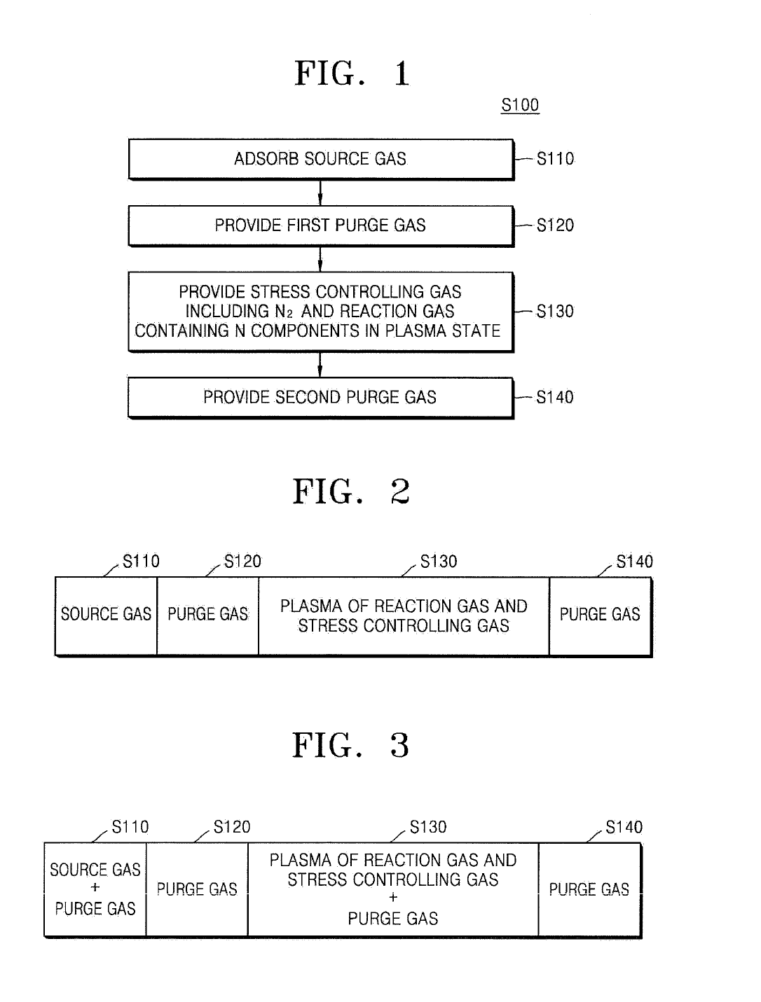

FIG. 1 is a flowchart illustrating a unit cycle of an atomic layer deposition process in a method of fabricating a nitride film according to an exemplary embodiment of the present invention.

Referring to FIG. 1, the method of fabricating a nitride film according to the exemplary embodiment of the present invention is a method of forming a nitride film having compressive stress on a substrate by performing a unit cycle (S100) including a first step (S110), a second step (S120), a third step (S130), and a fourth step (S140) at least one time.

The nitride film may be understood as a nitride film formed by the atomic layer deposition (ALD) in which a source gas, a purge gas, a reaction gas, and the like are provided on a substrate by a time division system or a space division system. The technical spirit of the present invention may be applied to not only a time division system in which deposition is implemented by discontinuously providing a source gas, a reaction gas, and the like into a chamber, in which a substrate is disposed, according to the time, but also a space division system in which deposition is implemented by sequentially moving a substrate in a system in which a source gas, a reaction gas, and the like are continuously provided while being spatially separated.

In the first step (S110), at least a part of the source gas may be adsorbed on the substrate by providing the source gas on the substrate. Examples of the substrate may include a semiconductor substrate, a conductor substrate, or an insulating substrate, and the like, and optionally, any pattern or layer may be already formed on the substrate before the nitride film having compressive stress is formed. The adsorption may include chemical adsorption which is widely known in the atomic layer deposition.

The source gas may be appropriately selected according to the kind of nitride film to be formed.

For example, when the nitride film to be formed is a silicon nitride film, the source gas may include at least one selected from the group consisting of silane, disilane, trimethylsilyl (TMS), tris(dimethylamino)silane (TDMAS), bis(tertiary-butylamino)silane (BTBAS), and dichlorosilane (DCS).

Further, for example, when the nitride film to be formed is a titanium nitride film, the source gas may include at least one selected from the group consisting of tetrakis(dimethylamino) titanium (TDMAT), tetrakis (ethylmethylamino) titanium (TEMAT), and tetrakis (diethylamino) titanium (TDETAT).

For example, when the nitride film to be formed is a tantalum nitride film, the source gas may include at least one selected from the group consisting of Ta[N(CH₃)₂]₅, Ta[N(C₂H₅)₂]₅, Ta(OC₂H₅)₅, and Ta(OCH₃)₅.

Of course, the kinds of above-described nitride film and source gas are illustrative, and the technical spirit of the present invention is not limited to the kind of exemplified material.

In the second step (S120), a first purge gas may be provided on the substrate. The first purge gas may remove at least a part of the other portions of the source gas, except for a portion adsorbed on the substrate, from the substrate.

That is, in the first step (S110), the source gas which is not adsorbed on the substrate may be purged by the first purge gas. The first purge gas may be a nitrogen gas, an inert gas, or a mixture gas composed of a nitrogen gas and an inert gas.

In the third step (S130), a unit deposition film may be formed on the substrate by simultaneously or sequentially providing the substrate with a stress controlling gas including a nitrogen gas (N₂) and a reaction gas containing nitrogen components (N) other than the nitrogen gas (N₂) in a plasma state.

The unit deposition film is a thin film constituting a nitride film to be formed, and for example, when the unit cycle (S100) is performed repeatedly N times (N is a positive integer of 1 or more), the nitride film to be finally formed may be composed of the N unit deposition films.

The stress controlling gas is a gas which is provided in order to control the stress of the unit deposition film, that is, the stress of the nitride film, and the present inventors confirmed that when a stress controlling gas including a nitrogen gas (N₂) is provided in the third step (S130), the stress of the nitride film may be effectively controlled.

For example, in the third step, the dimension of the compressive stress of the nitride film may be controlled by controlling the amount of a nitrogen gas (N₂) constituting the stress controlling gas, which is provided on the substrate. Specifically, in the third step, the present inventors confirmed that the larger the amount of a nitrogen gas (N₂) constituting the stress controlling gas, which is provided on the substrate, the nitride film having the larger compressive stress may be implemented.

The nitrogen gas (N₂) has a non-polar covalent bond, and has stability when present in a non-polar covalent bond, and in contrast, for example, in the third step (S130), the nitrogen gas (N₂) is ionized in the form of N₂⁺ and/or N⁺, and the like by the plasma. In this case, the ionization energy of N₂⁺ and/or N⁺ is very large, and an Si—N bond is formed in order to be present in a more stable form, for example, when the nitride film to be formed is a silicon nitride film. In this case, it is understood that a strong bond with Si is created and strong compressive stress is produced by strong ionization energy.

Meanwhile, the reaction gas containing nitrogen components (N) may be chemically reacted with the source gas adsorbed on the substrate to implement a unit deposition film constituting a nitride film. Here, the nitrogen components (N) constituting the reaction gas mean nitrogen components except for the nitrogen gas (N₂) constituting the stress controlling gas. For example, the reaction gas containing nitrogen components (N) may include an ammonia (NH₃) gas.

The plasma mentioned in the present application may be formed by a direct plasma system or a remote plasma system.

The direct plasma system includes, for example, a system in which by providing the reaction gas and the stress controlling gas to a treatment space between an electrode and a substrate and applying high frequency power to the treatment space, a plasma of the reaction gas and the stress controlling gas is directly formed in the treatment space in a chamber.

The remote plasma system includes, for example, a system in which the plasma of the reaction gas and the stress controlling gas is activated in a remote plasma generator and is introduced into a chamber, and may have an advantage in that damage to parts in a chamber such as an electrode is minimal and generation of particles may be reduced as compared to a direct plasma.

Meanwhile, in addition to this, the plasma mentioned in the present application may be formed in a shower head disposed on the substrate. In this case, the material in a plasma state may be provided to the treatment space on the substrate, for example, through jet holes formed on the shower head.

In the fourth step (S140), a second purge gas may be provided on the substrate. The second purge gas may remove at least a part of the stress controlling gas and the reaction gas, which are physically and/or chemically reacted with the source gas adsorbed on the substrate and are remaining on the substrate, from the substrate.

That is, in the fourth step (S140), at least a part of the stress controlling gas and the reaction gas, which are physically and/or chemically reacted with the source gas adsorbed on the substrate and are remaining on the substrate, may be purged by the second purge gas.

The second purge gas may be a nitrogen gas, an inert gas, or a mixture gas composed of a nitrogen gas and an inert gas.

The technical spirit of the present invention relates to a method of controlling stress of a nitride film in a process of forming the nitride film by the atomic layer deposition, and to form a nitride film having compressive stress on a substrate by performing a unit cycle at least one time, the unit cycle including simultaneously providing the substrate with a stress controlling gas including a nitrogen gas (N₂) and a reaction gas containing nitrogen components (N) other than the nitrogen gas (N₂) in a plasma state, in which the dimension of the compressive stress may be controlled by controlling the amount of nitrogen gas (N₂).

FIG. 2 is a diagram sequentially illustrating a series of processes, to which a substrate is subjected over time during a unit cycle in the method of fabricating a nitride film according to an exemplary embodiment of the present invention, from the left side to the right side. The present exemplary embodiment may make reference to the fabrication method of FIG. 1, and accordingly, the overlapped description will be omitted.

Referring to FIG. 2, for example, at least one of the first purge gas in the second step (S120) and the second purge gas in the fourth step (S140) may include a nitrogen gas (N₂). In the third step (S130), the reaction gas may include an ammonia (NH₃) gas, and the stress controlling gas may include a nitrogen gas (N₂).

Referring to FIG. 2, for another example, at least one of the first purge gas in the second step (S120) and the second purge gas in the fourth step (S140) may include an inert gas. In the third step (S130), the reaction gas may include an ammonia (NH₃) gas, and the stress controlling gas may include a nitrogen gas (N₂).

Referring to FIG. 2, for yet another example, at least one of the first purge gas in the second step (S120) and the second purge gas in the fourth step (S140) may be a mixture gas including a nitrogen gas (N₂) and an inert gas. In the third step (S130), the reaction gas may include an ammonia (NH₃) gas, and the stress controlling gas may include a nitrogen gas (N₂) and an inert gas.

Meanwhile, the present inventors confirmed that the higher the relative ratio of the nitrogen gas (N₂) to the inert gas in the stress controlling gas in the third step (S130) is, the larger the compressive stress of the finally implemented nitride film becomes, and the higher the relative ratio of the inert gas to the nitrogen gas (N₂) in the stress controlling gas in the third step (S130) is, the smaller the compressive stress of the finally implemented nitride film becomes.

Accordingly, when the stress controlling gas includes a nitrogen gas (N₂) and an inert gas, it is possible to expect an effect in that the compressive stress of the nitride film may be easily and precisely controlled by controlling a relative ratio of the nitrogen gas (N₂) to the inert gas in the third step (S130).

FIG. 3 is a diagram sequentially illustrating a series of processes, to which a substrate is subjected over time during a unit cycle in a modified method of fabricating a nitride film according to an exemplary embodiment of the present invention, from the left side to the right side. The present fabrication method may make reference to the fabrication method described in FIG. 2, and accordingly, the overlapped description will be omitted.

Referring to FIG. 3, the first purge gas provided in the second step (S120) or the second purge gas provided in the fourth step (S140) may be constantly provided in the first step (S110) to the fourth step (S140). That is, in the first step (S110), the first purge gas or the second purge gas may be provided on the substrate, and in the third step (S130), the first purge gas or the second purge gas may be provided on the substrate.

The purge gas provided in the first step (S110) may serve as a carrier of the source gas, and allows the source gas to be uniformly dispersed and adsorbed on the substrate.

Similarly, the purge gas provided in the third step (S130) may serve as a carrier which allows the reaction gas and the stress controlling gas to be uniformly dispersed and adsorbed on the substrate.

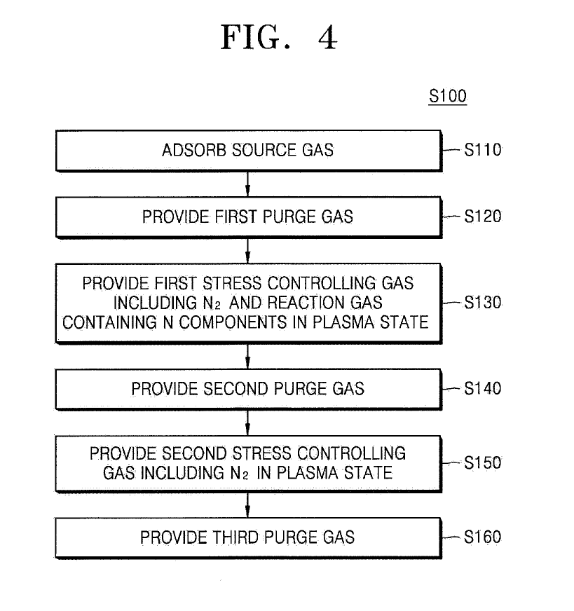

FIG. 4 is a flowchart illustrating a unit cycle of the atomic layer deposition process in a method of fabricating a nitride film according to another exemplary embodiment of the present invention. The present fabrication method may make reference to the fabrication method described in FIG. 1, and accordingly, the overlapped description will be omitted.

Referring to FIG. 4, the unit cycle (S100) may further include, after the fourth step (S140), a fifth step (S150) of providing a second stress controlling gas in a plasma state on the unit deposition film and a sixth step (S160) of providing a third purge gas on the substrate. In this case, in order to differentiate the stress controlling gases in the third step (S130) and the fifth step (S150) for convenience, the stress controlling gas in the third step (S130) may be referred to as a first stress controlling gas, and the stress controlling gas in the fifth step (S150) may be referred to as a second stress controlling gas.

The second stress controlling gas may include a nitrogen gas (N₂). For example, the second stress controlling gas may be composed of only a nitrogen gas (N₂).

Alternatively, the second stress controlling gas may include a mixture gas of an inert gas and a nitrogen gas (N₂).

In the fifth step (S150), a predetermined stress distribution may be further precisely implemented on the film quality of the unit deposition film already formed by providing the second stress controlling gas in a plasma state on the substrate to perform the first step (S110) to the fourth step (S140).

The nitrogen gas (N₂) disclosed in the third step (S130) is differentiated from the nitrogen gas (N₂) disclosed in the fifth step (S150), in that the nitrogen gas (N₂) disclosed in the third step (S130) is provided on the substrate simultaneously with the reaction gas, but the nitrogen gas (N₂) disclosed in the fifth step (S150) is provided on the substrate separately from the reaction gas after the reaction gas is purged.

In the sixth step (S160), a third purge gas may be provided on the substrate. The third purge gas may remove at least a part of the nitrogen gas (N₂) provided in the fifth step (S150) from the substrate.

That is, in the sixth step (S160), at least a part of the second stress controlling gas provided in the fifth step (S150) may be purged by the third purge gas. The third purge gas may be a nitrogen gas, an inert gas, or a mixture gas composed of a nitrogen gas and an inert gas.

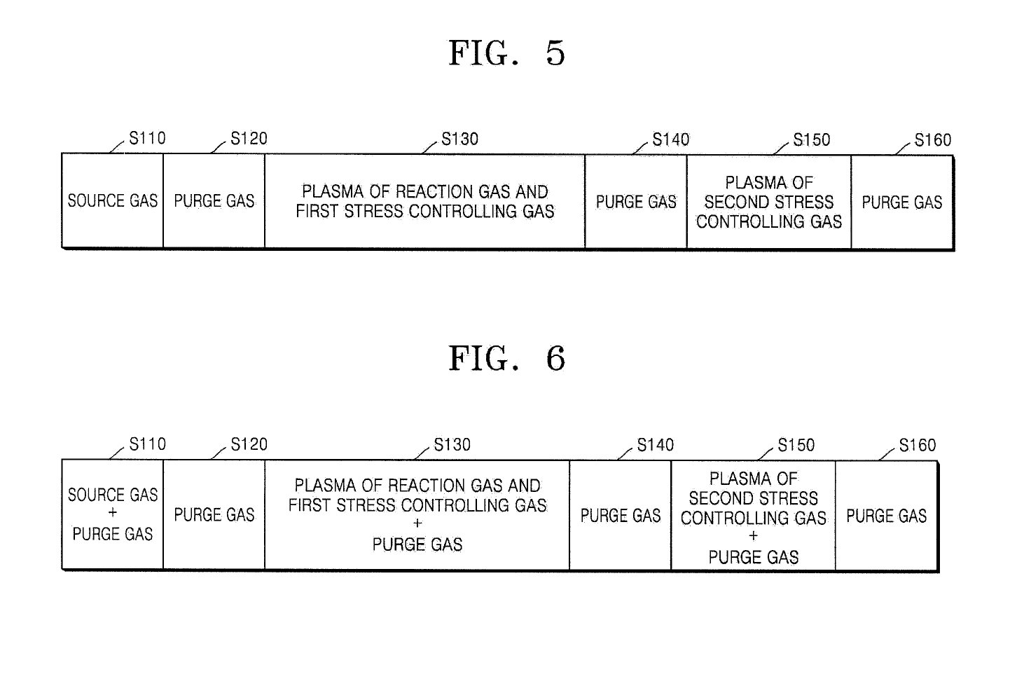

The above-described fifth step (S150) and sixth step (S160) may be each additionally applied to the exemplary embodiments specifically disclosed in FIGS. 2 and 3, and will be each described with reference to FIGS. 5 and 6.

FIG. 5 is a diagram sequentially illustrating a series of processes, to which a substrate is subjected over time during a unit cycle in the method of fabricating a nitride film according to another exemplary embodiment of the present invention, from the left side to the right side, and the above-described fifth step (S150) and sixth step (S160) are additionally applied to the exemplary embodiment illustrated in FIG. 2. The present exemplary embodiment may make reference to the fabrication methods of FIGS. 1, 2, and 4, and accordingly, the overlapped description will be omitted.

Referring to FIG. 5, for example, at least one of the first purge gas in the second step (S120), the second purge gas in the fourth step (S140), and the third purge gas in the sixth step (S160) may include a nitrogen gas (N₂). The reaction gas in the third step (S130) includes an ammonia (NH₃) gas. The stress controlling gas in the third step (S130) and the fifth step (S150) may include a nitrogen gas (N₂) or may include a mixture gas of an inert gas and a nitrogen gas (N₂).

Referring to FIG. 5, for another example, at least one of the first purge gas in the second step (S120), the second purge gas in the fourth step (S140), and the third purge gas in the sixth step (S160) may include an inert gas. The reaction gas in the third step (S130) includes an ammonia (NH₃) gas. The stress controlling gas in the third step (S130) and the fifth step (S150) may include a nitrogen gas (N₂) or may include a mixture gas of an inert gas and a nitrogen gas (N₂).

Referring to FIG. 5, for another example, at least one of the first purge gas in the second step (S120), the second purge gas in the fourth step (S140), and the third purge gas in the sixth step (S160) may be a mixture gas including a nitrogen gas (N₂) and an inert gas. The reaction gas in the third step (S130) includes an ammonia (NH₃) gas. The stress controlling gas in the third step (S130) and the fifth step (S150) may include a nitrogen gas (N₂) or may include a mixture gas of an inert gas and a nitrogen gas (N₂).

FIG. 6 is a diagram sequentially illustrating a series of processes, to which a substrate is subjected over time during a unit cycle in the modified method of fabricating a nitride film according to another exemplary embodiment of the present invention, from the left side to the right side. The present fabrication method may make reference to the fabrication method described in FIG. 5, and accordingly, the overlapped description will be omitted.

Referring to FIG. 6, the first purge gas provided in the second step (S120), the second purge gas provided in the fourth step (S140), or the third purge gas provided in the sixth step (S160) may be constantly provided in the first step (S110) to the sixth step (S160). That is, the first purge gas, the second purge gas, or the third purge gas in the first step (S110), the third step (S130), or the fifth step (S150) may be provided on the substrate.

The purge gas provided in the first step (S110) may serve as a carrier of the source gas, and allows the source gas to be uniformly dispersed and adsorbed on the substrate. The purge gas provided in the third step (S130) may serve as a carrier which allows the reaction gas and the first stress controlling gas to be uniformly dispersed and adsorbed on the substrate. The purge gas provided in the fifth step (S150) may serve as a carrier which allows the plasma of the second stress controlling gas to be uniformly dispersed and provided on the substrate.

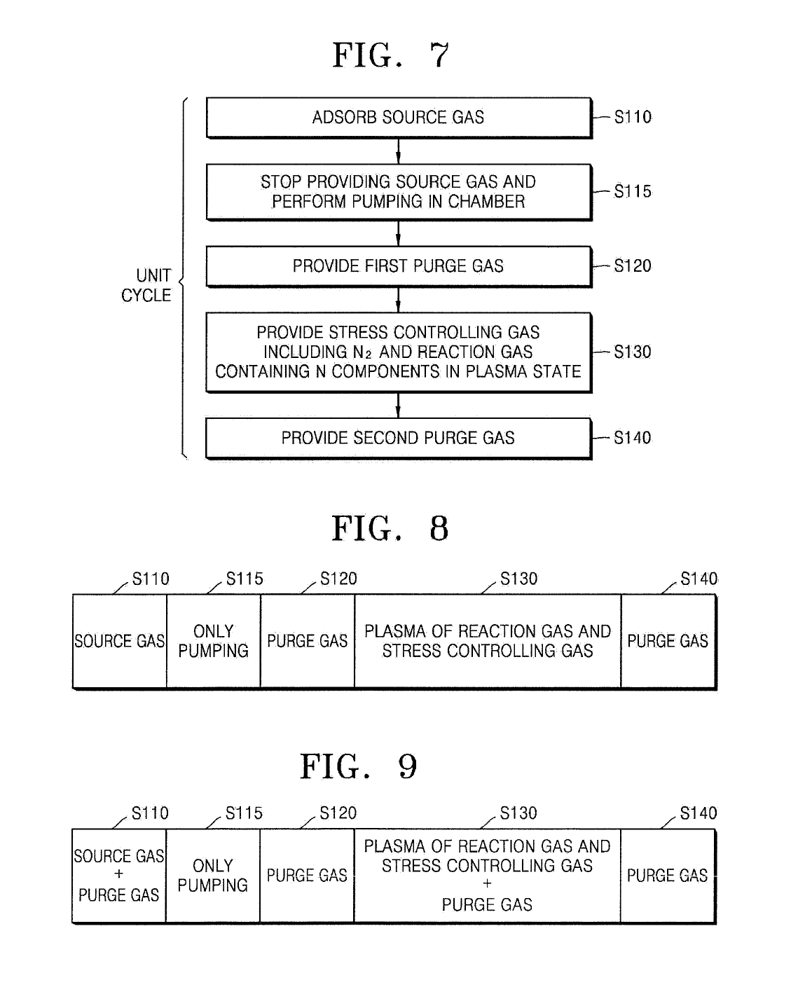

FIG. 7 is a flowchart illustrating a unit cycle of an atomic layer deposition process in a method of fabricating a nitride film according to still another exemplary embodiment of the present invention. The present fabrication method may make reference to the fabrication method described in FIG. 1, and accordingly, the overlapped description will be omitted.

Referring to FIG. 7, the method of fabricating a nitride film according to still another exemplary embodiment of the present invention is characterized in that the unit cycle includes the first step (S110), the second step (S120), the third step (S130), and the fourth step (S140) illustrated in FIG. 1, and further includes a step (S115) of stopping providing the source gas and maintaining the pressure in the chamber lower than the pressure in the chamber in the first step after the first step (S110) and before the second step (S120). The pressure in the chamber in the step (S115) may be lower than the pressure in the chamber in the first step (S110) by, for example, 10% to 90%.

By introducing the step (S115) between the first step (S110) and the second step (S120), the residual material of the source gas remaining without being adsorbed on the substrate may be further effectively removed, and a relatively good quality nitride may be deposited thereby. In particular, when a structure on a substrate on which a nitride is deposited is a level difference structure having a large aspect ratio, an effect of improving the step coverage of the nitride by the step (S115) may be further conspicuous.

For example, the step (S115) may be implemented by stopping providing the source gas and performing pumping in the chamber. More specifically, the step (S115) may be understood as a step in which only pumping is performed in a state where a source gas, a reaction gas, a purge gas, a post-treatment gas, and the like are not provided into the chamber.

Meanwhile, the pumping performed in the step (S115) may be performed all the time throughout the unit cycle. For example, the pumping in the chamber may be continuously performed during the first step (S110), the step (S115), the second step (S120), the third step (S130), and the fourth step (S140), which constitute the unit cycle.

FIG. 8 is a diagram sequentially illustrating a series of processes, to which a substrate is subjected over time during a unit cycle in the method of fabricating a nitride film according to still another exemplary embodiment of the present invention, from the left side to the right side. The present exemplary embodiment may make reference to the fabrication method of FIG. 7, and accordingly, the overlapped description will be omitted.

First, referring to FIG. 8, the nitride film may be implemented by repeatedly performing only the unit cycle including the first step (S110), the step (S115) in which only pumping is performed, the second step (S120), the third step (S130), and the fourth step (S140) at least one time.

The pumping performed in the step (S115) may be performed even in the first step (S110), the second step (S120), the third step (S130), and the fourth step (S140), but the step (S115) in which only pumping is performed needs to be understood as a step in which only the pumping is performed in a state where the source gas, the stress controlling gas, the reaction gas, the purge gas, and the like are not provided into the chamber.

Referring to FIG. 8, for example, at least one of the first purge gas in the second step (S120) and the second purge gas in the fourth step (S140) may include a nitrogen gas (N₂). In the third step (S130), the reaction gas includes an ammonia (NH₃) gas, and the stress controlling gas may include a nitrogen gas (N₂).

Referring to FIG. 8, for another example, at least one of the first purge gas in the second step (S120) and the second purge gas in the fourth step (S140) may include an inert gas such as an argon gas (Ar). In the third step (S130), the reaction gas includes an ammonia (NH₃) gas, and the stress controlling gas may include a nitrogen gas (N₂).

Referring to FIG. 8, for still another example, at least one of the first purge gas in the second step (S120) and the second purge gas in the fourth step (S140) may be a mixture gas including a nitrogen gas (N₂) and an inert gas. In the third step (S130), the reaction gas includes an ammonia (NH₃) gas, and the stress controlling gas may include a nitrogen gas (N₂) and an inert gas.

The higher the relative ratio of the nitrogen gas (N₂) to the inert gas in the stress controlling gas in the third step (S130) is, the larger the compressive stress of the finally implemented nitride film becomes, and the higher the relative ratio of the inert gas to the nitrogen gas (N₂) in the stress controlling gas in the third step (S130) is, the smaller the compressive stress of the finally implemented nitride film becomes.

Accordingly, when the stress controlling gas includes a nitrogen gas (N₂) and an inert gas, it is possible to expect an effect in that the compressive stress of the nitride film may be easily and precisely controlled by controlling a relative ratio of the nitrogen gas (N₂) to the inert gas in the third step (S130).

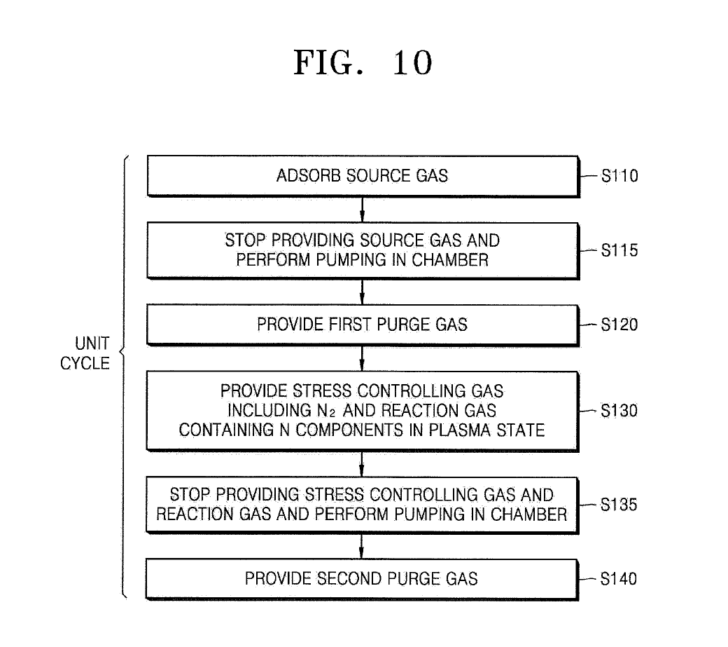

FIG. 9 is a diagram sequentially illustrating a series of processes, to which a substrate is subjected over time during a unit cycle in a modified method of fabricating a nitride film according to yet another exemplary embodiment of the present invention, from the left side to the right side.

Referring to FIG. 9, the nitride film may be implemented by repeatedly performing only the unit cycle including the first step (S110), the step (S115) in which only pumping is performed, the second step (S120), the third step (S130), and the fourth step (S140) at least one time. The description on the step (S115) in which only pumping is performed is substantially the same as the contents mentioned by referring to FIG. 8, and thus, will be herein omitted.

Referring to FIG. 9, the first purge gas provided in the second step (S120) or the second purge gas provided in the fourth step (S140) may be constantly provided in the first step (S110) to the fourth step (S140). That is, in the first step (S110), the first purge gas or the second purge gas may be provided on the substrate, and in the third step (S130), the first purge gas or the second purge gas may be provided on the substrate.

The purge gas provided in the first step (S110) may serve as a carrier of the source gas, and allows the source gas to be uniformly dispersed and adsorbed on the substrate.

Similarly, the purge gas provided in the third step (S130) may serve as a carrier which allows the reaction gas and the stress controlling gas to be uniformly dispersed and adsorbed on the substrate.

Meanwhile, the method of fabricating a nitride film according to the modified exemplary embodiment of the present invention may include both a step in which the first unit cycle illustrated in FIG. 8 is performed at least one time and a step in which the second unit cycle illustrated in FIG. 9 is performed at least one time. The disposing sequence, the repetition time, and the like of the first unit cycle and the second unit cycle may be appropriately designed according to the characteristics of a required nitride film.

FIG. 10 is a flowchart illustrating a unit cycle of an atomic layer deposition process in a method of fabricating a nitride film according to still yet another exemplary embodiment of the present invention. The present fabrication method may make reference to the fabrication method described in FIG. 7, and accordingly, the overlapped description will be omitted. That is, the present fabrication method is different from the fabrication method described in FIG. 7, in that a step (S135) is added, and accordingly, since the other steps are overlapped, the description thereof will be omitted.

Referring to FIG. 10, the fabrication method includes a step (S135) of stopping providing the stress controlling gas and the reaction gas into the chamber and maintaining the pressure in the chamber lower than the pressure in the chamber in the third step after the third step (S130) and before the fourth step (S140). The pressure in the chamber in the step (S135) may be lower than the pressure in the chamber in the third step (S130) by, for example, 10% to 90%.

By introducing the step (S135) between the third step (S130) and the fourth step (S140), the residual material of the reaction gas remaining without being reacted with the source gas adsorbed on the substrate and the residual material of the stress controlling gas may be further effectively removed, and a relatively good quality nitride may be deposited thereby. In particular, when a structure on a substrate on which a nitride is deposited is a level difference structure having a large aspect ratio, an effect of improving the step coverage of the nitride by the step (S135) may be further remarkable.

For example, the step (S135) may be implemented by stopping providing the stress controlling gas and the reaction gas, and performing pumping in the chamber. More specifically, the step (S135) may be understood as a step in which only pumping is performed in a state where a source gas, a stress controlling gas, a reaction gas, a purge gas, and the like are not provided into the chamber.

Meanwhile, the step (S115) and the step (S135), which constitute the unit cycle, are the same as each other, in that the two steps are a step in which only pumping is performed in a state where no gas is provided into the chamber, but the two steps may be differentiated from each other, in that the step (S115) is a step of stopping providing the source gas and pumping the chamber, and the step (S135) is a step of stopping providing the stress controlling gas and the reaction gas and pumping the chamber.

Meanwhile, the pumping in the chamber may be performed all the time throughout the unit cycle as well as in the step (S135). For example, the pumping in the chamber may be continuously performed during the first step (S110), the above-described step (S115), the second step (S120), the third step (S130), the above-described step (S135), and the fourth step (S140), which constitute the unit cycle.

Meanwhile, even though not separately illustrated in the drawings, in a fabrication method according to yet another modified exemplary embodiment of the present invention, the unit cycle for forming the nitride film illustrated in FIG. 10 may further include a fifth step (S150) of providing a second stress controlling gas in a plasma state on a unit deposition film and a sixth step (S160) of providing a third purge gas on the substrate after the fourth step (S140), as described in FIG. 4. In this case, in order to differentiate the stress controlling gases in the third step (S130) and the fifth step (S150) for convenience, the stress controlling gas in the third step (S130) may be referred to as a first stress controlling gas, and the stress controlling gas in the fifth step (S150) may be referred to as a second stress controlling gas.

The second stress controlling gas may include a nitrogen gas (N₂). For example, the second stress controlling gas may be composed of only a nitrogen gas (N₂).

Alternatively, the second stress controlling gas may include a mixture gas of an inert gas and a nitrogen gas (N₂).

In the fifth step (S150), a predetermined stress distribution may be further precisely implemented on the film quality of the unit deposition film already formed by providing the second stress controlling gas in a plasma state on the substrate to perform the first step (S110) to the fourth step (S140).

The nitrogen gas (N₂) disclosed in the third step (S130) is differentiated from the nitrogen gas (N₂) disclosed in the fifth step (S150), in that the nitrogen gas (N₂) disclosed in the third step (S130) is provided on the substrate simultaneously with the reaction gas, but the nitrogen gas (N₂) disclosed in the fifth step (S150) is provided on the substrate separately from the reaction gas after the reaction gas is purged.

In the sixth step (S160), a third purge gas may be provided on the substrate. The third purge gas may remove at least a part of the nitrogen gas (N₂) provided in the fifth step (S150) from the substrate.

That is, in the sixth step (S160), at least a part of the second stress controlling gas provided in the fifth step (S150) may be purged by the third purge gas. The third purge gas may be a nitrogen gas, an inert gas, or a mixture gas composed of a nitrogen gas and an inert gas.

According to the above-described exemplary embodiments, a method of controlling the compressive stress of a nitride film may be provided in the fabrication of the nitride film by an atomic layer deposition in which the unit cycle is repeatedly performed at least one time. For example, the unit cycle includes a step of simultaneously providing a substrate with a stress controlling gas including a nitrogen gas (N₂) and a reaction gas containing nitrogen components (N) other than the nitrogen gas (N₂) in a plasma state, and may be performed by controlling the amount of nitrogen gas, which is provided on the substrate, to be increased as the compressive stress required for the nitride film is increased, thereby controlling the compressive stress of the nitride film. Furthermore, the unit cycle may additionally include a step of providing a stress controlling gas including a nitrogen gas (N₂) in a plasma state on a substrate after a unit deposition film is formed, thereby effectively controlling the compressive stress of the nitride film.

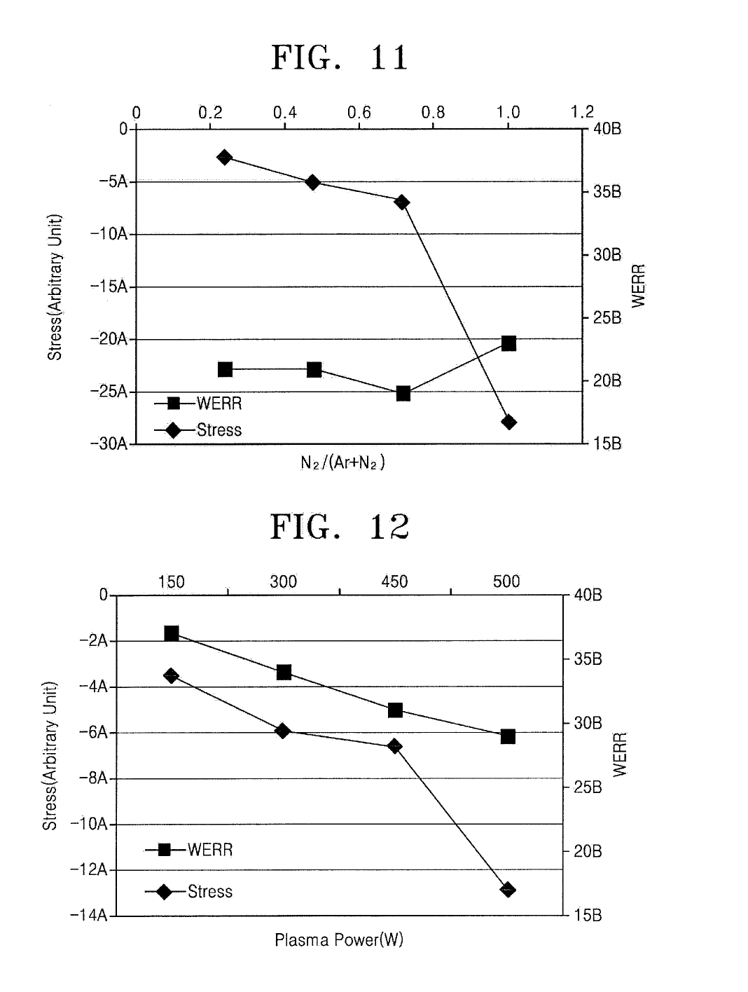

FIG. 11 is a graph illustrating characteristics of compressive stress and a wet etch rate ratio (WERR) according to the relative flow rate of a nitrogen gas in a nitride film implemented by a fabrication method according to some exemplary embodiments of the present invention, and FIG. 12 is a graph illustrating characteristics of compressive stress and a wet etch rate ratio (WERR) according to the plasma power in a nitride film implemented by a fabrication method according to a Comparative Example of the present invention.

The exemplary embodiment disclosed in FIG. 11 corresponds to the case where a nitride film described by referring to FIG. 4 is fabricated, and the Comparative Example described in FIG. 12 corresponds to the case where a nitride film having compressive stress is fabricated by controlling the power of plasma without providing a stress controlling gas including a nitrogen gas (N₂).

In FIGS. 11 and 12, the vertical axis at the left side indicates the dimension of the compressive stress of the nitride film, and the vertical axis at the right side indicates the wet etch rate ratio (WERR) which indicates the film quality of the nitride film. For mutual comparison, unit value A of FIG. 11 is the same as unit value A of FIG. 12, and unit value B of FIG. 11 is the same as unit value B of FIG. 12. In FIGS. 11 and 12, an argon gas was used as an inert gas.

Referring to FIG. 11, it can be confirmed that the higher the relative ratio of a nitrogen gas (N₂) to an inert gas in a stress controlling gas composed of the nitrogen gas (N₂) and the inert gas becomes (that is, as the value of the horizontal axis in FIG. 11 is increased), the higher the compressive stress of the finally implemented nitride film becomes.

Meanwhile, in the method of fabricating a nitride film according to exemplary embodiments of the present invention, it can be confirmed that even though the compressive stress of the nitride film is increased, there is no relatively large variation in wet etch rate ratio (WERR) which exhibits the film quality of the nitride film.

In contrast, referring to FIG. 12, in the Comparative Example of the present invention, in which a nitride film is formed without using a stress controlling gas including a nitrogen gas (N₂), it can be confirmed that the compressive stress of the nitride film may be increased by increasing the plasma power, but simultaneously, there is a relatively large variation in wet etch rate ratio (WERR) which exhibits the film quality of the nitride film.

This suggests that it is possible to control the power (or frequency) of a power supply applied for forming a plasma in a unit cycle of an atomic layer deposition process for controlling the stress of the nitride film, but in this case, the change in film quality is relatively significant according to the power or frequency of the plasma.

In contrast, according to the exemplary embodiments of the present invention, it can be seen that when a plasma is formed in a unit cycle of an atomic layer deposition process, the compressive stress of the nitride film may be controlled by controlling a mixture ratio of a nitrogen gas (N₂) and an inert gas, and in this case, the film quality of the nitride film may be maintained at relatively the same level regardless of the compressive stress of the nitride film.

In the modified exemplary embodiments of the present invention, when a plasma is formed in a unit cycle of an atomic layer deposition process as a method of controlling the compressive stress of the nitride film, the ratio of the nitrogen gas (N₂) may be controlled, and simultaneously, the frequency or power of a power supply applied for forming the plasma (this may also be referred to as a plasma power or frequency) may be additionally controlled. According to these modified exemplary embodiments, it is possible to expect an effect in that the range of the compressive stress of the nitride film may be further widely controlled while the film quality of the nitride film is fairly maintained.

For example, when a very high level of the compressive stress of the nitride film is required, plasma damage may be generated on the surface of the nitride film by controlling the frequency or power of the plasma to deposit the nitride film, but the case of depositing the nitride film by additionally controlling the frequency or power of the plasma simultaneously while controlling the flow rate of the nitrogen gas (N₂) is advantageous in that a very high compressive stress may be implemented without a plasma damage on the surface of the nitride film.

The present invention has been described with reference to the exemplary embodiments illustrated in the drawings, but the exemplary embodiments are only illustrative, and it would be appreciated by the person skilled in the art that various modifications and other equivalent exemplary embodiments can be made. Therefore, the true technical scope of the present invention shall be defined by the technical spirit of the appended claims.

What is claimed is:

1. A method of fabricating a nitride film, in which a nitride film having compressive stress is formed on a substrate by performing a unit cycle at least one time, the unit cycle comprising:
a first step of providing a source gas on the substrate to adsorb at least a part of the source gas on the substrate;
a second step of providing a first purge gas on the substrate;
a third step of forming a unit deposition film on the substrate by providing the substrate with a stress controlling gas comprising a nitrogen gas (N₂) and a reaction gas containing nitrogen components (N) other than the nitrogen gas (N₂) in a plasma state; and
a fourth step of providing a second purge gas on the substrate.

2. The method of claim 1, wherein as compressive stress required for the nitride film is increased, the amount of nitrogen gas (N₂) provided on the substrate in the third step is increased.

3. The method of claim 1, wherein the stress controlling gas comprises a mixture gas of a nitrogen gas (N₂) and an inert gas.

4. The method of claim 3, wherein as the compressive stress required for the nitride film is increased in the third step, a relative ratio of the nitrogen gas (N₂) to the inert gas provided on the substrate is increased.

5. The method of claim 3, wherein the inert gas comprises at least one of helium (He), neon (Ne), argon (Ar), krypton (Kr), xenon (Xe), and radon (Rn).

6. The method of claim 1, wherein the plasma is formed by a direct plasma system or a remote plasma system.

7. The method of claim 1, wherein the first purge gas or the second purge gas is constantly provided in the first to fourth steps.

8. The method of claim 1, wherein at least one of the first purge gas and the second purge gas is a nitrogen gas, an inert gas, or a mixture gas composed of a nitrogen gas and an inert gas.

9. The method of claim 1, wherein the stress controlling gas is a gas composed of a material which is the same as at least one of the first purge gas and the second purge gas.

10. The method of claim 1, wherein the unit cycle comprises:
a fifth step of providing a second stress controlling gas in a plasma state on the unit deposition film; and
a sixth step of providing a third purge gas on the substrate.

11. The method of claim 10, wherein the second stress controlling gas comprises a nitrogen gas (N₂), or comprises a mixture gas of an inert gas and a nitrogen gas (N₂).

12. The method of claim 10, wherein the first purge gas, the second purge gas, or the third purge gas is constantly provided in the first to sixth steps.

13. The method of claim 10, wherein at least one of the first purge gas, the second purge gas, and the third purge gas is a nitrogen gas, an inert gas, or a mixture gas composed of a nitrogen gas and an inert gas.

14. The method of claim 10, wherein the second stress controlling gas is a gas composed of a material which is the same as at least one of the first purge gas, the second purge gas, and the third purge gas.

15. The method of claim 1, wherein the unit cycle comprises a step of stopping providing the source gas and maintaining a pressure in the chamber lower than the pressure in the chamber in the first step after the first step and before the second step.

16. The method of claim 15, wherein the maintaining of the pressure in the chamber lower than the pressure in the chamber in the first step is implemented by performing pumping in the chamber while stopping providing the source gas.

17. The method of claim 16, wherein the pumping is performed all the time throughout the unit cycle.

18. The method of claim 15, wherein the unit cycle comprises a step of stopping providing the stress controlling gas and the reaction gas and maintaining a pressure in the chamber lower than the pressure in the chamber in the third step after the third step and before the fourth step.

19. The method of claim 18, wherein the maintaining of the pressure in the chamber lower than the pressure in the chamber in the third step is implemented by performing pumping in the chamber while stopping providing the stress controlling gas and the reaction gas.

20. The method of claim 19, wherein the pumping is performed all the time throughout the unit cycle.
